(19) United States
(12) Patent Application Publication
(10) Pub. No.: US 2026/0135556 A1
(43) Pub. Date: May 14, 2026

(54) Contactor Control System

(71) Applicants: Tyco Electronics (Shanghai) Co., Ltd., Shanghai (CN); Tyco Electronics Technology (SIP) Co., Ltd., Suzhou (CN)

(72) Inventors: Jimmy Wang, Shanghai (CN); Xinhui (Robert) Mao, Shanghai (CN); Xianghu Shen, Suzhou (CN); Xuejun Liu, Shanghai (CN); Yisong Wu, Shanghai (CN)

(73) Assignees: Tyco Electronics (Shanghai) Co., Ltd., Shanghai (CN); Tyco Electronics Technology (SIP) Co., Ltd., Suzhou (CN)

(21) Appl. No.: 19/386,392

(22) Filed: Nov. 12, 2025

(30) Foreign Application Priority Data
Nov. 12, 2024 (CN) 202411614158.8

(51) Int. Cl. H03K 17/687; G05F 1/46; H02M 3/145

(52) U.S. Cl. CPC H03K 17/687; G05F 1/46; H02M 3/145

(57) ABSTRACT

A contactor control system includes a switch circuit, a control circuit, a current detection circuit, a DC/DC converter and a diode. The switch circuit is adapted to be connected between one end of a contactor coil and a positive electrode of a power supply, and to be switched between an on state and an off state. The control circuit controls the switch circuit to switch between the on state and the off state. During a start-up phase of the contactor coil, the control circuit controls the switch circuit to switch to the on state and maintain it for a predetermined time, and during a holding phase of the contactor coil, the control circuit controls the switch circuit to switch to the open state to cut off an electrical connection between one end of the contactor coil and a positive electrode of the power supply.

### CROSS-REFERENCE TO RELATED APPLICATION

This application claims the benefit of Chinese Patent Application No. CN202411614158.8 filed on Nov. 12, 2024 in the State Intellectual Property Office of China, the whole disclosure of which is incorporated herein by reference.

### FIELD OF THE INVENTION

The disclosure relates to a contactor control system.

### BACKGROUND OF THE INVENTION

A high voltage contactor is a key component in high-voltage distribution systems. When starting the contactor, a relatively large starting current is required, while when holding it, only a small holding current is needed. In the prior art, the core competitive advantage of high-voltage contactors is their small size, which matches customers' demand for miniaturization applications. In the prior art, the holding current of the contactor coil is affected by fluctuations in the power supply voltage and operating temperature, which can cause fluctuations in the holding current and affect the reliability of the contactor operation. In order to ensure stable holding current of the contactor coil, voltage compensation and temperature compensation are required for the contactor control system in the prior art. However, this contactor control system based on voltage compensation and temperature compensation has the problems of complex structure and high cost.

### SUMMARY OF THE INVENTION

According to an embodiment of the present disclosure, a contactor control system includes a switch circuit, a control circuit, a current detection circuit, a DC/DC converter and a diode. The switch circuit is adapted to be connected between one end of a contactor coil and a positive electrode of a power supply, and to be switched between an on state and an off state. The control circuit controls the switch circuit to switch between the on state and the off state. The current detection circuit is connected to another end of the contactor coil, and is adapted to detect a current flowing through the contractor coil in real-time. The DC/DC converter has a feedback end connected to an output end of the current detection circuit. The diode has a positive electrode connected to an output end of the DC/DC converter and a negative electrode connected to the one end of the contactor coil. During a start-up phase of the contactor coil, the control circuit controls the switch circuit to switch to the on state and maintain it for a predetermined time, and during a holding phase of the contactor coil, the control circuit controls the switch circuit to switch to the open state to cut off an electrical connection between one end of the contactor coil and a positive electrode of the power supply.

### BRIEF DESCRIPTION OF DRAWINGS

The above and other features of the present invention will become more apparent by describing in detail exemplary embodiments thereof with reference to the accompanying drawings, in which:

FIG. 1 shows a functional block diagram of a contactor control system according to an exemplary embodiment of the present invention; and

FIG. 2 shows a circuit diagram of a contactor control system according to an exemplary embodiment of the present invention.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to an embodiment of the present disclosure, a contactor control system comprises: a switch circuit which is to be connected between one end of a contactor coil and a positive electrode of a power supply, and is adapted to be switched between the on state and the off state; a control circuit for controlling the switch circuit to switch between the on state and the off state; a current detection circuit connected to the other end of the contactor coil, used for real-time detection of the current flowing through the contactor coil; a DC/DC converter, whose feedback end FB is connected to the output end of the current detection circuit; and a diode D2, with its positive electrode connected to the output end VDD_AJ of the DC/DC converter and its negative electrode used to connect to the one end of the contactor coil. During the start-up phase of the contactor coil, the control circuit controls the switch circuit to switch to the on state and maintain it for a predetermined time t, in order to connect the electrical connection between one end of the contactor coil and the positive electrode of the power supply; during the holding phase of the contactor coil, the control circuit controls the switch circuit to switch to the open state to cut off the electrical connection between one end of the contactor coil and the positive electrode of the power supply.

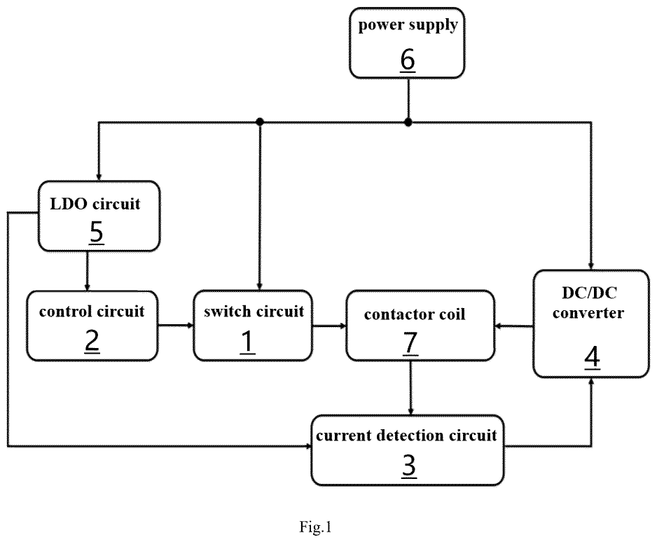

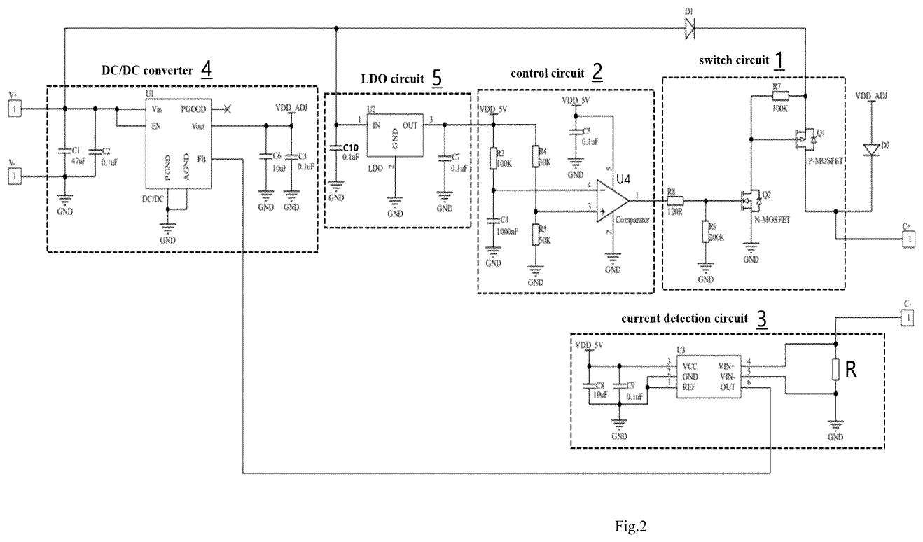

FIG. 1 shows a functional block diagram of a contactor control system according to an exemplary embodiment of the present invention. FIG. 2 shows a circuit diagram of a contactor control system according to an exemplary embodiment of the present invention.

As shown in FIGS. 1 and 2, in an exemplary embodiment of the present invention, a contactor control system is disclosed. The contactor control system includes: a switch circuit 1, a control circuit 2, a current detection circuit 3, a DC/DC converter 4, and a diode D2. The switch circuit 1 is used to be connected between one end C+ of a contactor coil 7 and a positive electrode V+ of a power supply 6, and is adapted to be switched between the on state and the off state. The control circuit 2 is used to control the switch circuit 1 to switch between the on and off states. The current detection circuit 3 is connected to the other end C− of the contactor coil 7 for real-time detection of the current flowing through the contactor coil 7. The feedback end FB of the DC/DC converter 4 is connected to the output end of the current detection circuit 3. The positive electrode of diode D2 is connected to the output end VDD_ADJ of the DC/DC converter 4, and the negative electrode of diode D2 is used to connect to one end C+ of contactor coil 7.

In the illustrated embodiment, during the start-up phase of the contactor coil 7, the control circuit 2 controls the switch circuit 1 to switch to the on state and maintain it for a predetermined time t, in order to connect the electrical connection between one end C+ of the contactor coil 7 and the positive electrode V+ of the power supply 6. During the holding phase of contactor coil 7, the control circuit 2 controls the switch circuit 1 to switch to the off state to cut off the electrical connection between one end C+ of contactor coil 7 and the positive electrode V+ of power supply 6.

During the start-up phase of the contactor coil 7, the output voltage of the DC/DC converter 4 at the output end is lower than the power supply voltage V1 of the power supply 6. The diode D2 is used to prevent the power supply voltage V1 from being reverse applied to the output end of the DC/DC converter 4.

During the start-up phase of contactor coil 7, the switch circuit 1 connects the positive electrode V+ of the power supply 6 and one end C+ of the contactor coil 7 to provide power to the contactor coil 7 through the power supply 6.

The starting current I1 of the contactor coil 7 can be calculated according to the following formula:

I1=V1/Rc, among which

V1 is the power supply voltage of power supply 6, and Rc is the resistance of contactor coil 7.

During the holding phase of the contactor coil 7, the switch circuit 1 cuts off the electrical connection between the positive electrode V+ of the power supply 6 and one end C+ of the contactor coil 7, in order to supply power to the contactor coil 7 through the output end of the DC/DC converter 4.

During the holding phase of the contactor coil 7, the current detection circuit 3 detects the holding current I2 flowing through the contactor coil 7 in real time. The DC/DC converter 4 adjusts the output voltage of the DC/DC converter 4 based on the holding current I2 detected by the current detection circuit 3 until the holding current I2 detected by the current detection circuit 3 is equal to a predetermined holding current I.

When the holding current I2 detected by the current detection circuit 3 is greater than the predetermined holding current I, the DC/DC converter 4 gradually decreases the output voltage until the holding current I2 detected by the current detection circuit 3 is equal to the predetermined holding current I. When the holding current I2 detected by the current detection circuit 3 is less than the predetermined holding current I, the DC/DC converter 4 gradually increases the output voltage until the holding current I2 detected by the current detection circuit 3 is equal to the predetermined holding current I.

The contactor control system also includes an LDO circuit 5. The input end of LDO circuit 5 is connected to the positive end V+ of power supply 6, and the output end of LDO circuit 5 is connected to the power ends of control circuit 2 and current detection circuit 3, used to provide stable power supply voltage to control circuit 2 and current detection circuit 3.

The control circuit 2 includes a comparator U4, a resistor R3, a capacitor C4, a resistor R4, and a resistor R5. The output end of comparator U4 is connected to the input end of switch circuit 1. One end of resistor R3 is connected to the output end of LDO circuit 5, and the other end of resistor R3 is connected to the inverting input of comparator U4. One end of capacitor C4 is connected to the other end of resistor R3, and the other end of capacitor C4 is grounded. One end of resistor R4 is connected to the output end of LDO circuit 5, and the other end of resistor R4 is connected to the in-phase input of comparator U4. One end of resistor R5 is connected to the other end of resistor R4, and the other end of resistor R5 is grounded.

In the illustrated embodiment, the control circuit 2 further includes a capacitor C5, one end of which is connected to the power end of the comparator U4, and the other end of which is grounded. The output end of LDO circuit 5 is connected to the power end of comparator U4, which is used to provide stable power supply voltage to comparator U4.

The switch circuit 1 includes a N-type MOS transistor Q2 and a P-type MOS transistor Q1. The gate of N-type MOS transistor Q2 is connected to the output end of control circuit 2, and the source of N-type MOS transistor Q2 is grounded. The gate of P-type MOS transistor Q1 is connected to the drain of N-type MOS transistor Q2, the source of P-type MOS transistor Q1 is used to connect to the positive electrode V+ of power supply 6, and the drain of P-type MOS transistor Q1 is used to connect to one end C+ of contactor coil 7.

The switch circuit 1 further includes resistors R7, R8, and R9. One end of resistor R7 is connected to the source of P-type MOS transistor Q1, and the other end of resistor R7 is connected to the gate of P-type MOS transistor Q1. One end of resistor R8 is connected to the output end of comparator U4, and the other end of resistor R8 is connected to the gate of N-type MOS transistor Q2. One end of resistor R9 is connected to the other end of resistor R8 and the gate of N-type MOS transistor Q2, and the other end of resistor R9 is grounded.

The switch circuit 1 further includes a diode D1. The positive electrode of the diode D1 is used to connect to the positive electrode V+ of the power supply 6, and the negative electrode of the diode D1 is connected to one end of the resistor R7 and the source of the P-type MOS transistor Q1.

When the charging time of capacitor C4 has not reached the predetermined time t, the voltage drop on capacitor C4 is less than the voltage drop on resistor R5. The voltage at the in-phase input of comparator U4 is higher than the voltage at its inverting input, and the output end of comparator U4 outputs a high level to drive N-type MOS transistor Q2 and P-type MOS transistor Q1 to conduct simultaneously, so that the switch circuit 1 is switched to the on state.

When the charging time of capacitor C4 has reached the predetermined time t, the voltage drop on capacitor C4 is greater than the voltage drop on resistor R5. The voltage at the in-phase input of comparator U4 is lower than the voltage at its inverting input, and the output end of comparator U4 outputs a low level to drive N-type MOS transistor Q2 and P-type MOS transistor Q1 to cut off simultaneously, causing the switch circuit 1 to be switched to the off state.

The current detection circuit 3 includes a sampling resistor R and a current detection chip U3. One end of the sampling resistor R is used to connect with the other end C− of the contactor coil 7, and the other end of the sampling resistor R is grounded. The positive input end VIN+ of the current detection chip U3 is connected to one end of the sampling resistor R, and the negative input end VIN− of the current detection chip U3 is connected to the other end of the sampling resistor R. The output end of the current detection chip U3 is connected to the feedback end FB of the DC/DC converter 4, and is used to feed back the holding current I2 detected by the current detection chip U3 to the feedback end FB of the DC/DC converter 4.

The current detection chip U3 collects the voltage drop V2 on the sampling resistor R through the positive input end VIN+ and the negative input end VIN−. The holding current I2 detected by the current detection chip U3 can be calculated according to the following formula:

I2=V2/R, among which

R is the resistance value of the sampling resistor R.

The power end VCC of the current detection chip U3 is connected to the output end of the LDO circuit 5, and the ground end GND and reference voltage end REF of the current detection chip U3 are grounded.

The current detection circuit 3 further includes capacitors C8 and C9. One ends of capacitors C8 and C9 are connected to the power end VCC of the current detection chip U3, and the other ends of capacitors C8 and C9 are connected to the ground end GND and the reference voltage end REF of the current detection chip U3.

The DC/DC converter 4 includes a DC/DC conversion chip U1. The input voltage pin VIN and enable pin EN of the DC/DC conversion chip U1 are used to connect to the positive electrode V+ of the power supply 6, and its power ground pin PGND and analog ground pin AGND are grounded. The output end Vout of the DC/DC conversion chip U1 is connected to the positive electrode of the diode D2, and the feedback end FB of the DC/DC conversion chip U1 is connected to the output end of the current detection chip U3.

The DC/DC converter 4 further includes capacitors C1 and C2, as well as capacitors C3 and C6. One ends of capacitors C1 and C2 are connected to the input voltage pin VIN of the DC/DC conversion chip U1, and the other ends of capacitors C1 and C2 are grounded. One ends of capacitor C3 and capacitor C6 are connected to the output end Vout of DC/DC conversion chip U1, and the other ends of capacitor C3 and capacitor C6 are grounded.

The LDO circuit 5 includes a low dropout linear regulator U2, a capacitor C10, and a capacitor C7. The input end of the low dropout linear regulator U2 is used to connect to the positive electrode V+ of the power supply 6. One end of capacitor C10 is connected to the input end of low dropout linear regulator U2, and the other end of capacitor C10 is grounded. One end of capacitor C7 is connected to the output end of low dropout linear regulator U2, and the other end of capacitor C7 is grounded. The output end of the low dropout linear regulator U2 is connected to the input end of the control circuit 2, the power end of the comparator U4, and the power end VCC of the current detection chip U3, to provide them with a stable 5V supply voltage.

It should be noted that in this application, unless otherwise specified, “grounded” refers to “connected to the negative electrode V− of power supply 6”.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A contactor control system, comprising:
a switch circuit which is to be connected between one end of a contactor coil and a positive electrode of a power supply, and is adapted to be switched between the on state and the off state;
a control circuit for controlling the switch circuit to switch between the on state and the off state;
a current detection circuit connected to the other end of the contactor coil, used for real-time detection of the current flowing through the contactor coil;
a DC/DC converter, whose feedback end FB is connected to the output end of the current detection circuit; and
a diode D2, with its positive electrode connected to the output end VDD_AJ of the DC/DC converter and its negative electrode used to connect to the one end of the contactor coil, wherein:
during the start-up phase of the contactor coil, the control circuit controls the switch circuit to switch to the on state and maintain it for a predetermined time t, in order to connect the electrical connection between one end of the contactor coil and the positive electrode of the power supply; and
during the holding phase of the contactor coil, the control circuit controls the switch circuit to switch to the open state to cut off the electrical connection between one end of the contactor coil and the positive electrode of the power supply.

2. The contactor control system according to claim 1, wherein during the start-up phase of the contactor coil, the output voltage of the output end of the DC/DC converter is lower than the power supply voltage V1 of the power supply, and the diode D2 is used to prevent the power supply voltage V1 from being reverse applied to the output end of the DC/DC converter.

3. The contactor control system according to claim 2, wherein:
during the start-up phase of the contactor coil, the switch circuit connects the positive electrode of the power supply and one end of the contactor coil to provide power to the contactor coil through the power supply; and
the starting current I1 of the contactor coil can be calculated according to the following formula:
$$I 1 = V 1 / Rc ,$$
wherein
V1 is the power supply voltage of the power supply, and Rc is the resistance of the contactor coil.

4. The contactor control system according to claim 1, wherein during the holding phase of the contactor coil, the switch circuit cuts off the electrical connection between the positive electrode of the power supply and one end of the contactor coil to supply power to the contactor coil through the output end of the DC/DC converter.

5. The contactor control system according to claim 4, wherein during the holding phase of the contactor coil, the current detection circuit detects in real-time the holding current I2 flowing through the contactor coil, the DC/DC converter adjusts the output voltage of the output end of the DC/DC converter based on the holding current I2 detected by the current detection circuit until the holding current I2 detected by the current detection circuit is equal to a predetermined holding current I.

6. The contactor control system according to claim 5, wherein:
when the holding current I2 detected by the current detection circuit is greater than the predetermined holding current I, the DC/DC converter gradually reduces the output voltage until the holding current I2 detected by the current detection circuit is equal to the predetermined holding current I; and
when the holding current I2 detected by the current detection circuit is less than the predetermined holding current I, the DC/DC converter gradually increases the output voltage until the holding current I2 detected by the current detection circuit is equal to the predetermined holding current I.

7. The contactor control system according to claim 1, further comprising a LDO circuit which has an input end connected to the positive electrode of the power supply, and an output end connected to the power ends of the control circuit and the current detection circuit, for providing stable power supply voltage to the control circuit and the current detection circuit.

8. The contactor control system according to claim 7, wherein the control circuit comprises:
a comparator U4, whose output end is connected to the input end of the switch circuit;
a resistor R3, one end of which is connected to the output end of the LDO circuit, and the other end of which is connected to the inverting input of the comparator U4;
a capacitor C4, one end of which is connected to the other end of resistor R3 and the other end is grounded;
a resistor R4, one end of which is connected to the output end of the LDO circuit, and the other end of which is connected to the in-phase input of the comparator U4; and
a resistor R5, one end of which is connected to the other end of resistor R4, and the other end is grounded.

9. The contactor control system according to claim 8, wherein the control circuit further comprises a capacitor C5, one end of which is connected to the power end of comparator U4, and the other end is grounded, wherein the output end of the LDO circuit is connected to the power end of the comparator U4, used to provide stable power supply voltage to the comparator U4.

10. The contactor control system according to claim 8, wherein the switch circuit comprises:
a N-type MOS transistor Q2, with its gate connected to the output end of the control circuit and its source grounded; and
a P-type MOS transistor Q1, with its gate connected to the drain of N-type MOS transistor Q2, its source connected to the positive electrode of the power supply, and its drain connected to one end of the contactor coil.

11. The contactor control system according to claim 10, wherein the switch circuit further comprises:
a resistance R7, one end of which is connected to the source of P-type MOS transistor Q1, and the other end of which is connected to the gate of P-type MOS transistor Q1;
a resistor R8, one end of which is connected to the output end of comparator U4 and the other end of which is connected to the gate of N-type MOS transistor Q2; and
a resistor R9, one end of which is connected to the other end of resistor R8 and the gate of N-type MOS transistor Q2, and the other end is grounded.

12. The contactor control system according to claim 11, wherein the switch circuit further comprises a diode D1, the positive electrode of which is connected to the positive electrode of the power supply, and its negative electrode is connected to one end of resistor R7 and the source of P-type MOS transistor Q1.

13. The contactor control system according to claim 10, wherein when the charging time of the capacitor C4 does not reach the predetermined time t, the voltage drop on the capacitor C4 is less than the voltage drop on the resistor R5, and the voltage at the in-phase input of the comparator U4 is higher than the voltage at its inverting input, the output end of the comparator U4 outputs a high level to drive the N-type MOS transistor Q2 and the P-type MOS transistor Q1 to conduct simultaneously, so that the switch circuit is switched to the on state.

14. The contactor control system according to claim 10, wherein when the charging time of the capacitor C4 reaches the predetermined time t, the voltage drop on the capacitor C4 is greater than the voltage drop on the resistor R5, and the voltage at the in-phase input of the comparator U4 is lower than the voltage at its inverting input, the output end of the comparator U4 outputs a low level to drive the N-type MOS transistor Q2 and the P-type MOS transistor Q1 to cut off simultaneously, causing the switch circuit to be switched to the off state.

15. The contactor control system according to claim 8, wherein the current detection circuit comprises:
a sampling resistor R, one end of which is used to connect with the other end of the contactor coil, and the other end is grounded; and
a current detection chip U3 which has a positive input end VIN+ connected to one end of the sampling resistor R, and a negative input end VIN− connected to the other end of the sampling resistor R, wherein the output end of the current detection chip U3 is connected to the feedback end FB of the DC/DC converter, and is used to feed back the holding current I2 detected by the current detection chip U3 to the feedback end FB of the DC/DC converter.

16. The contactor control system according to claim 15, wherein:
the current detection chip U3 collects the voltage drop V2 on the sampling resistor R through the positive input end VIN+ and the negative input end VIN−; and
the holding current I2 detected by the current detection chip U3 can be calculated according to the following formula:
$$I 2 = V 2 / R ,$$
wherein
R is the resistance value of the sampling resistor R.

17. The contactor control system according to claim 15, wherein the power end VCC of the current detection chip U3 is connected to the output end of the LDO circuit, and the ground end GND and reference voltage end REF of the current detection chip U3 are grounded.

18. The contactor control system according to claim 17, wherein the current detection circuit further comprises a capacitor C8 and a capacitor C9, one ends of which are connected to the power end VCC of the current detection chip U3, and the other ends of which are connected to the ground end GND and reference voltage end REF of the current detection chip U3.

19. The contactor control system according to claim 15, wherein the DC/DC converter comprises a DC/DC conversion chip U1 which has an input voltage pin VIN and an enable pin EN for connecting to the positive electrode of the power supply, and its power ground pin PGND and analog ground pin AGND are grounded, wherein the output end Vout of the DC/DC conversion chip U1 is connected to the positive end of the diode D2, and the feedback end FB of the DC/DC conversion chip U1 is connected to the output end of the current detection chip U3.

20. The contactor control system according to claim 19, wherein the DC/DC converter further comprises:
a capacitor C1 and a capacitor C2, one ends of which are connected to the input voltage pin VIN of the DC/DC conversion chip U1, and the other ends of which are grounded; and
a capacitor C3 and a capacitor C6, one ends of which are connected to the output end Vout of the DC/DC conversion chip U1, and the other ends of which are grounded.

21. The contactor control system according to claim 15, wherein the LDO circuit comprises:
a low voltage drop linear regulator U2, whose input end is used to connect with the positive electrode of the power supply;
a capacitor C10, one end of which is connected to the input end of the low dropout linear regulator U2, and the other end is grounded; and
a capacitor C7, one end of which is connected to the output end of the low voltage difference linear regulator U2, and the other end is grounded, wherein the output end of the low dropout linear regulator U2 is connected to the input end of the control circuit, the power end of the comparator U4, and the power end VCC of the current detection chip U3, for providing them with a stable 5V supply voltage.
